(19) United States
(12) Patent Application Publication
(10) Pub. No.: US 2012/0319125 A1
(43) Pub. Date: Dec. 20, 2012

(54) SILICON CARBIDE SUBSTRATE AND METHOD OF MANUFACTURING THE SAME

(75) Inventors: Tsutomu HORI, Itami-shi (JP); Shin HARADA, Osaka-shi (JP); Keiji ISHIBASHI, Itami-shi (JP); Shinsuke FUJIWARA, Itami-shi (JP)

(73) Assignee: SUMITOMO ELECTRIC INDUSTRIES, LTD., Osaka-shi (JP)

(21) Appl. No.: 13/494,317

(22) Filed: Jun. 12, 2012

Related U.S. Application Data
(60) Provisional application No. 61/539,141, filed on Sep. 26, 2011.

(30) Foreign Application Priority Data
Jun. 16, 2011 (JP) 2011-134050
Sep. 26, 2011 (JP) 2011-208675

(51) Int. Cl. H01L 29/16; H01L 21/31

(52) U.S. Cl. 257/76; 438/758; 257/E29.082; 257/E21.24

(57) ABSTRACT

A first single crystal substrate has a first side surface and it is composed of silicon carbide. A second single crystal substrate has a second side surface opposed to the first side surface and it is composed of silicon carbide. A bonding portion connects the first and second side surfaces to each other between the first and second side surfaces. At least a part of the bonding portion is made of particles composed of silicon carbide and having a maximum length not greater than 1 μm.

### BACKGROUND OF THE INVENTION

1. Field of the Invention

The present invention relates to a silicon carbide substrate and a method of manufacturing the same, and particularly to a silicon carbide substrate having a plurality of single crystal substrates and a method of manufacturing the same.

2. Description of the Background Art

Industrially, a silicon carbide substrate (an SiC substrate) having single crystal structure has had a size of approximately 100 mm (4 inches) at the maximum, which is smaller than a size of a silicon substrate widely used for manufacturing a semiconductor device. This fact leads to lower efficiency in manufacturing a semiconductor device including a silicon carbide substrate. The problem above is particularly serious in particular in the case of using a property of a plane other than a (0001) plane in SiC of hexagonal system, which will be described below.

An SiC substrate having fewer defects is usually manufactured by cutting an SiC ingot obtained by growth on the (0001) plane, which is less likely to cause stacking faults. Hence, an SiC substrate having a plane orientation other than the (0001) plane is obtained by cutting the ingot not in parallel to its grown surface. Therefore, it has been difficult to secure a sufficient size of the substrate or most of the ingot cannot effectively be used. For this reason, it is particularly difficult to efficiently manufacture a semiconductor device that makes use of a plane other than the (0001) plane of SiC.

Instead of simply increasing a size of a silicon carbide substrate with such difficulty, it is considered to use a silicon carbide substrate having a supporting portion and a plurality of single crystal substrates of high quality arranged thereon. Since the supporting portion does not have to have such high quality, it is relatively easy to prepare a large supporting portion. Therefore, a silicon carbide substrate having a necessary size can be obtained by increasing the number of single crystal substrates placed on this large supporting portion.

In such a silicon carbide substrate, however, gaps are inevitably formed between adjacent single crystal substrates. In a gap, foreign matters are likely to accumulate during a process of manufacturing a semiconductor device using this silicon carbide substrate. An exemplary foreign matter is a cleaning liquid or a polishing agent used in the process of manufacturing a semiconductor device or dust in an atmosphere. It is difficult to completely remove foreign matters by cleaning, because they are present in a small gap. Therefore, the foreign matters result in lowering in manufacturing yield, which leads to lower efficiency in manufacturing semiconductor devices. Then, several methods for closing an opening of a gap have been proposed. For example, in the method disclosed in WO2011/058830 (Patent Literature 1), sublimates are deposited. Alternatively, in the method disclosed in WO2011/058831 (Patent Literature 2), introduction and carbonization of molten silicon are carried out.

With the conventional methods above, however, in some cases, large stress is produced in a portion closing an opening of a gap, which results in great warpage of a substrate. If a semiconductor device is manufactured with an excessively warped substrate, yield may be lowered owing thereto.

### SUMMARY OF THE INVENTION

The present invention was made in view of the above-described problems and its object is to provide a large-sized silicon carbide substrate allowing manufacturing of semiconductor devices with high yield and a method of manufacturing the same.

A silicon carbide substrate according to one aspect of the present invention has first and second single crystal substrates and a bonding portion. The first single crystal substrate has a first side surface and it is composed of silicon carbide. The second single crystal substrate has a second side surface opposed to the first side surface and it is composed of silicon carbide. The bonding portion connects the first and second side surfaces to each other between the first and second side surfaces. At least a part of the bonding portion is made of particles composed of silicon carbide and having a maximum length not greater than 1 μm.

In the silicon carbide substrate according to one aspect above, since silicon carbide forming the bonding portion has a small particle size, many grain boundaries are formed in the bonding portion. As stress in the bonding portion is thus mitigated, warpage of the substrate can be suppressed. Therefore, lowering in yield due to warpage of the substrate is suppressed in manufacturing a semiconductor device with the use of this substrate.

In the silicon carbide substrate according to one aspect above, preferably, at least a part of the bonding portion occupies 30 volume % or more of the bonding portion.

In the silicon carbide substrate according to one aspect above, preferably, the bonding portion includes particles having a maximum length exceeding 1 μm and composed of a material having a melting point not lower than 1600° C.

A silicon carbide substrate according to another aspect of the present invention has first and second single crystal substrates and a bonding portion. The first single crystal substrate has a first side surface and it is composed of silicon carbide. The second single crystal substrate has a second side surface opposed to the first side surface and it is composed of silicon carbide. The bonding portion connects the first and second side surfaces to each other between the first and second side surfaces. In a cross-sectional view of the bonding portion, a ratio of an area of a region occupied by particles composed of silicon carbide and having a maximum length not greater than 1 μm to a total area of the cross-sectional view of the bonding portion is not lower than 2%.

In the silicon carbide substrate according to another aspect above, since silicon carbide forming the bonding portion has a small particle size, many grain boundaries are formed in the bonding portion. As stress in the bonding portion is thus mitigated, warpage of the substrate can be suppressed. Therefore, lowering in yield due to warpage of the substrate is suppressed in manufacturing a semiconductor device with the use of this substrate.

In the silicon carbide substrate according to another aspect above, preferably, the bonding portion includes in the cross-sectional view, particles composed of silicon carbide and having a maximum length exceeding 1 μm.

The silicon carbide substrate above preferably further has a supporting portion supporting each of the first and second single crystal substrates.

In the silicon carbide substrate above, preferably, the supporting portion is composed of silicon carbide.

A method of manufacturing a silicon carbide substrate according to the present invention has the following steps. A combined substrate including a first single crystal substrate having a first back surface and a first side surface, a second single crystal substrate having a second back surface and a second side surface, and a supporting portion bonded to each of the first and second back surfaces is prepared. A gap having an opening is formed between the first and second side surfaces as a result of the first and second side surfaces opposed to each other. A fluid portion connecting the first and second side surfaces to each other is formed by injecting a fluid containing at least any of polycarbosilane and a derivative thereof through the opening of the gap. A bonding portion burying at least a part of the gap is formed by solidifying the fluid portion through heat treatment.

In the method of manufacturing a silicon carbide substrate above, preferably, in the step of forming a bonding portion, the heat treatment is performed at a temperature not lower than 800° C. and not higher than 2000° C.

In the method of manufacturing a silicon carbide substrate above, preferably, the step of forming a fluid portion includes the step of mixing in the fluid, particles having a maximum length exceeding 1 μm and composed of a material having a melting point not lower than 1600° C.

In the method of manufacturing a silicon carbide substrate above, preferably, the supporting portion is composed of silicon carbide.

It is noted that a “length” herein refers to a dimension in a certain direction. In addition, a “length” in a specific direction, which is maximum in “length”, is referred to as a “maximum length”.

As described above, according to the present invention, lowering in yield due to warpage of a substrate in manufacturing a semiconductor device can be suppressed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a construction of a silicon carbide substrate in a first embodiment of the present invention.

FIG. 2 is a schematic cross-sectional view along the line II-II in FIG. 1.

FIG. 3 is a schematic partial enlarged view of FIG. 2.

FIG. 4 is a plan view schematically showing a first step of a method for manufacturing a silicon carbide substrate in the first embodiment of the present invention.

FIG. 5 is a schematic cross-sectional view along the line V-V in FIG. 4.

FIG. 6 is a partial cross-sectional view schematically showing a second step of the method for manufacturing a silicon carbide substrate in the first embodiment of the present invention.

FIG. 7 is a diagram schematically showing a variation of FIG. 3.

FIG. 8 is a diagram schematically showing a variation of FIG. 6.

FIG. 9 is a partial cross-sectional view schematically showing a construction of a silicon carbide substrate in a second embodiment of the present invention.

FIG. 10 is a partial cross-sectional view schematically showing one step of a method for manufacturing a silicon carbide substrate in the second embodiment of the present invention.

FIG. 11 is a diagram schematically showing a variation of FIG. 9.

FIG. 12 is a diagram schematically showing a variation of FIG. 10.

FIG. 13 is a cross-sectional view showing one example of a microstructure of a bonding portion in FIG. 11.

FIG. 14 is a cross-sectional view showing one example of a microstructure of a bonding portion in a comparative example.

FIG. 15 is a cross-sectional view schematically showing a first step of a method for manufacturing a silicon carbide substrate in a third embodiment of the present invention.

FIG. 16 is a cross-sectional view schematically showing a second step of the method for manufacturing a silicon carbide substrate in the third embodiment of the present invention.

FIG. 17 is a cross-sectional view schematically showing a third step of the method for manufacturing a silicon carbide substrate in the third embodiment of the present invention.

FIG. 18 is a cross-sectional view schematically showing one step of a method for manufacturing a silicon carbide substrate in a first variation of the third embodiment of the present invention.

FIG. 19 is a cross-sectional view schematically showing one step of a method for manufacturing a silicon carbide substrate in a second variation of the third embodiment of the present invention.

FIG. 20 is a cross-sectional view schematically showing one step of a method for manufacturing a silicon carbide substrate in a third variation of the third embodiment of the present invention.

FIG. 21 is a partial cross-sectional view schematically showing a construction of a semiconductor device in a fourth embodiment of the present invention.

FIG. 22 is a schematic flowchart of a method for manufacturing a semiconductor device in the fourth embodiment of the present invention.

FIG. 23 is a partial cross-sectional view schematically showing a first step of the method for manufacturing a semiconductor device in the fourth embodiment of the present invention.

FIG. 24 is a partial cross-sectional view schematically showing a second step of the method for manufacturing a semiconductor device in the fourth embodiment of the present invention.

FIG. 25 is a partial cross-sectional view schematically showing a third step of the method for manufacturing a semiconductor device in the fourth embodiment of the present invention.

FIG. 26 is a partial cross-sectional view schematically showing a fourth step of the method for manufacturing a semiconductor device in the fourth embodiment of the present invention.

### DESCRIPTION OF THE PREFERRED EMBODIMENTS

An embodiment of the present invention will be described hereinafter with reference to the drawings. It is noted that, in the drawings below, the same or corresponding elements have the same reference characters allotted and description thereof will not be repeated. In addition, an individual orientation, a collective orientation, an individual plane, and a collective plane are herein shown in [ ], < >, ( ) and { }, respectively. Moreover, in terms of crystallography, a negative index should be denoted by a number with a bar “-” thereabove, however, a negative sign herein precedes a number.

### First Embodiment

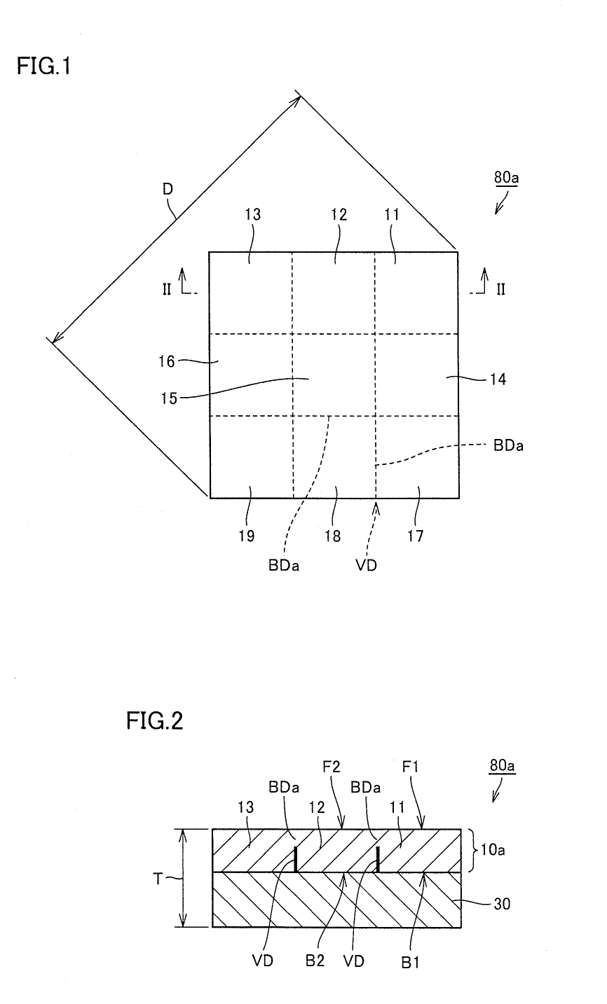

Referring to FIGS. 1 and 2, a silicon carbide substrate 80a in the present embodiment has a supporting portion 30, a supported portion 10a supported by supporting portion 30, and a bonding portion BDa. Supported portion 10a has single crystal substrates 11 to 19 composed of silicon carbide. Each of single crystal substrates 11 to 19 has a back surface and a front surface. For example, single crystal substrate 11 (a first single crystal substrate) has a back surface B1 (a first back surface) and a front surface F1 (a first front surface), while single crystal substrate 12 (a second single crystal substrate) has a back surface B2 (a second back surface) and a front surface F2 (a second front surface). Supporting portion 30 is bonded to the back surface of each of single crystal substrates 11 to 19.

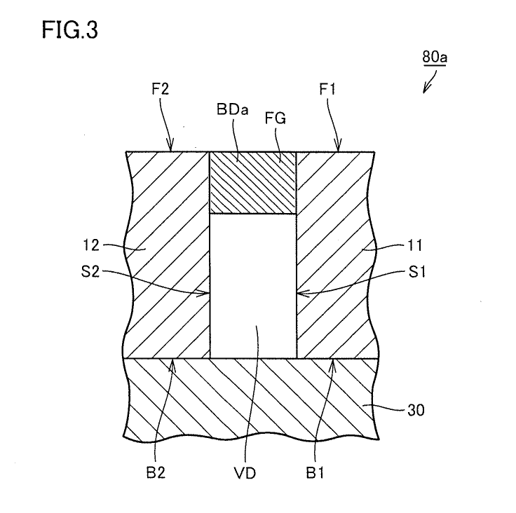

Referring further to FIG. 3, each of single crystal substrates 11 to 19 has a side surface. For example, single crystal substrate 11 has a side surface S1 (a first side surface), and single crystal substrate 12 has a side surface S2 (a second side surface) opposed to side surface S1. A gap VD is present between the side surfaces opposed to each other.

Bonding portion BDa connects to each other, the side surfaces opposed to each other between these side surfaces. For example, side surfaces S1 and S2 are connected to each other between side surfaces S1 and S2. A front surface side (an upper side in FIGS. 2 and 3) of gap VD is closed by bonding portion BDa. Bonding portion BDa includes, for example, a portion located between front surfaces F1 and F2, and hence front surfaces F1 and F2 are smoothly connected to each other.

Bonding portion BDa is composed substantially of silicon carbide. It is noted that hydrogen atoms may remain to some extent in bonding portion BDa for reasons in connection with a manufacturing process. Bonding portion BDa includes a fine particle portion FG. Fine particle portion FG is composed of silicon carbide having a particle size not greater than 1 μm. More specifically, fine particle portion FG is made of particles composed of silicon carbide and having a maximum length not greater than 1 μm. Preferably, a volume of fine particle portion FG occupies 2% or more of a volume of bonding portion BDa. More preferably, fine particle portion FG occupies 30 volume % or more of bonding portion BDa. Further preferably, substantially the entire bonding portion BDa is made of fine particle portion FG. Fine particle portion FG has a particle size, for example, around several hundred nm.

Fine particle portion FG includes a portion having polycrystalline structure. In other words, each of at least some of particles contained in fine particle portion FG has single crystal structure. Alternatively, fine particle portion FG may include a portion having amorphous structure.

Preferably, a ratio of a maximum length D (FIG. 1) in the plan view (FIG. 1) of silicon carbide substrate 80a with respect to a thickness T (FIG. 2) of silicon carbide substrate 80a is not lower than 50 and not higher than 500. Further preferably, maximum length D is not smaller than 100 mm.

Supporting portion 30 is preferably formed of a material capable of withstanding a temperature of 1800° C. or higher, such as silicon carbide, carbon, or a refractory metal. An exemplary refractory metal is molybdenum, tantalum, tungsten, niobium, iridium, ruthenium, or zirconium. When silicon carbide is employed as the material for supporting portion 30 from among the above, supporting portion 30 can have physical properties closer to those of single crystal substrates 11 to 19.

Though supporting portion 30 is provided in silicon carbide substrate 80a in the present embodiment, such a construction not including supporting portion 30 may be employed. This construction is obtained, for example, by removing supporting portion 30 of silicon carbide substrate 80a (FIG. 2) through polishing. Further, though a square shape is shown as a shape of silicon carbide substrate 80a in the plan view in FIG. 1, the shape is not limited to square and it may be, for example, circular. In a case where this shape is circular, a diameter of the circular shape represents maximum length D (FIG. 1).

A method for manufacturing silicon carbide substrate 80a in the present embodiment will now be described. For simplification of description below, only single crystal substrates 11 and 12 among single crystal substrates 11 to 19 may be mentioned, however, single crystal substrates 13 to 19 are also handled similarly to single crystal substrates 11 and 12.

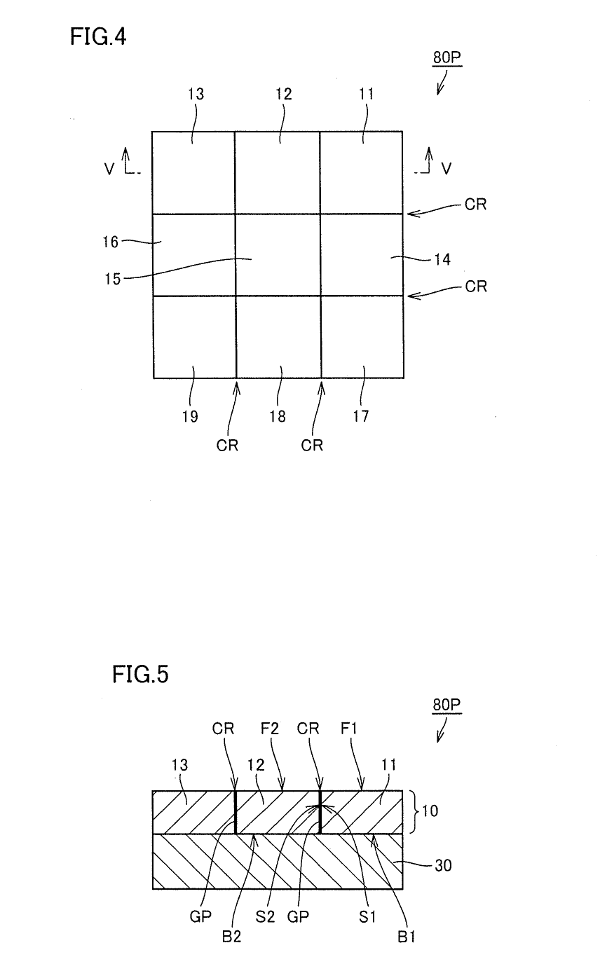

Referring to FIGS. 4 and 5, a combined substrate 80P is prepared. Combined substrate 80P has supporting portion 30 and a single crystal substrate group 10. Single crystal substrate group 10 includes single crystal substrates 11 and 12. Each of back surface B1 of single crystal substrate 11 and back surface B2 of single crystal substrate 12 is bonded to supporting portion 30. A gap GP is formed between side surface S1 of single crystal substrate 11 and side surface S2 of single crystal substrate 12. Gap GP has an opening CR between front surface F1 of single crystal substrate 11 and front surface F2 of single crystal substrate 12.

Then, a fluid containing polycarbosilane or a derivative thereof is prepared. Preferably, this fluid contains polycarbosilane. For example, xylene can be employed as a solvent of a solution. For example, a “precursor polymer” having a model number “RD-478” manufactured by Starfire Systems Inc. can be used as the fluid. It is noted that the fluid is not limited to a solution and the fluid may be, for example, a gel, a sol, or slurry.

Here, a “derivative” of polycarbosilane refers to a polymer having such a structure that at least any of an atom or a functional group of polycarbosilane has been substituted. Such substitution can be caused, for example, by an impurity unintentionally introduced during a process for manufacturing polycarbosilane.

Then, this fluid is injected to close opening CR of gap GP. Specifically, the fluid is applied. This injection can be carried out at a room temperature or at a temperature close thereto. It is noted that the fluid may be pressed against gap GP so that the fluid is further injected into gap GP. In addition, a pressure of an atmosphere around combined substrate 80P may be reduced after application so that the fluid is further injected into gap GP.

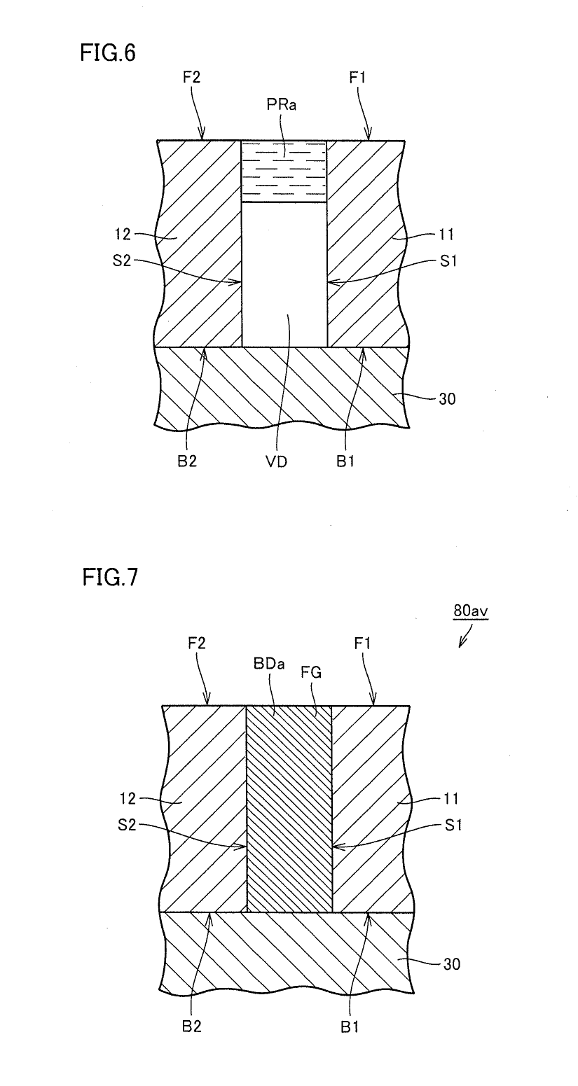

Referring to FIG. 6, a fluid portion PRa formed from the fluid is thus formed to connect side surfaces S1 and S2 to each other. Consequently, gap GP (FIG. 5) becomes gap VD closed by fluid portion PRa.

Then, fluid portion PRa is subjected to heat treatment. An atmosphere used for heat treatment preferably has a low oxygen partial pressure in order to prevent oxidation reaction, and an atmosphere is set preferably to an inert atmosphere or a vacuum atmosphere. A pressure of an atmosphere is preferably set to an atmospheric pressure or lower. A temperature for heat treatment is preferably not lower than 800° C., and it is set, for example, to approximately 1000° C. In a case where further sufficient removal of hydrogen contained in fluid portion PRa is desired, a temperature for heat treatment is preferably not lower than 1300° C. In a case where further sufficient crystallization of fluid portion PRa is desired, a temperature for heat treatment is preferably not lower than 1600° C. In addition, a temperature for heat treatment is set to 2000° C. or lower and preferably 1800° C. or lower, in order to suppress sublimation of silicon carbide. A time period for heat treatment is set, for example, to approximately 30 minutes. As a result of this heat treatment, fluid portion PRa changes to bonding portion BDa (FIG. 3), to thereby obtain silicon carbide substrate 80a (FIG. 3).

According to the present embodiment, as shown in FIG. 2, single crystal substrates 11 and 12 are combined as one silicon carbide substrate 80a through supporting portion 30. Silicon carbide substrate 80a includes both front surfaces F1 and F2 of the respective single crystal substrates as its substrate surface on which a semiconductor device such as a transistor is to be formed. In other words, silicon carbide substrate 80a has a substrate surface larger than in the case where any of single crystal substrates 11 and 12 is used alone. For example, maximum length D in the plan view (FIG. 1) of silicon carbide substrate 80a is not smaller than 100 mm. Thus, a semiconductor device can efficiently be manufactured by using silicon carbide substrate 80a.

Further, in the process of manufacturing silicon carbide substrate 80a, opening CR present between front surfaces F1 and F2 of combined substrate 80P (FIG. 5) is closed by bonding portion BDa (FIG. 2). Accordingly, front surfaces F1 and F2 become a surface smoothly connected to each other. As such, in the process of manufacturing a semiconductor device using silicon carbide substrate 80a, foreign matters, which would cause lowering in yield, are less likely to accumulate between front surfaces F1 and F2. Thus, use of silicon carbide substrate 80a allows manufacturing of semiconductor devices with high yield.

In addition, since bonding portion BDa has a small particle size, many grain boundaries are formed in bonding portion BDa. As stress in bonding portion BDa is thus mitigated, occurrence of warpage of silicon carbide substrate 80a can be suppressed.

Moreover, as supporting portion 30 bonded to each of single crystal substrates 11 and 12 is provided, single crystal substrates 11 and 12 can be coupled to each other more securely than in a case where bonding portion BDa alone couples single crystal substrates 11 and 12 to each other.

Further, in a case where a ratio of maximum length D (FIG. 1) in the plan view (FIG. 1) of silicon carbide substrate 80a with respect to thickness T (FIG. 2) of silicon carbide substrate 80a is not lower than 50, a size of silicon carbide substrate 80a in the plan view can sufficiently be secured. For example, in a case where D/T is 50, a silicon carbide substrate satisfying T=2 mm and D=100 mm is obtained. Furthermore, as this ratio is not higher than 500, warpage of silicon carbide substrate 80a can further be suppressed.

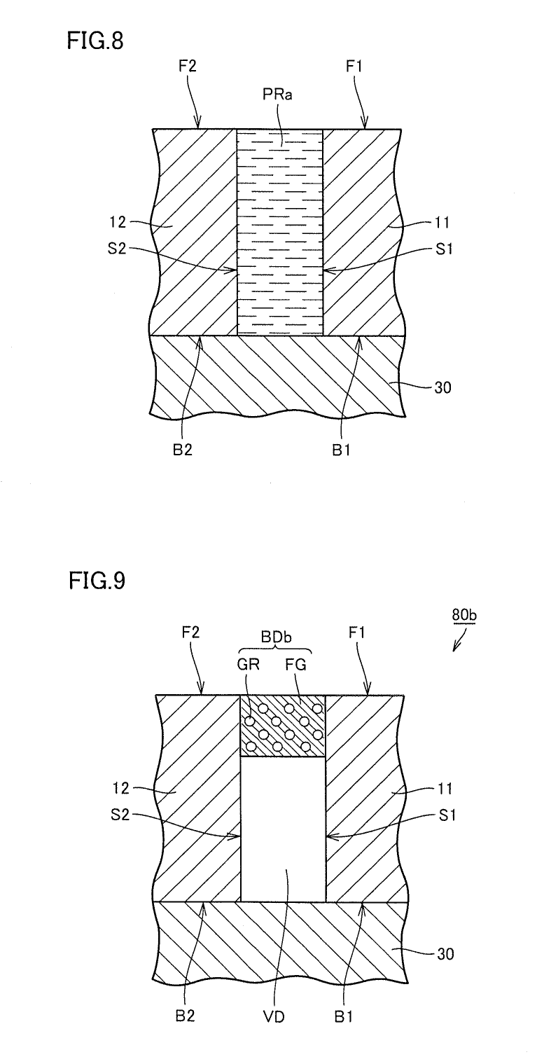

Though a case where gap VD (FIG. 3) remains has been described above, gap VD (FIG. 3) may be buried completely by bonding portion BDa as shown in FIG. 7. To that end, instead of the step shown in FIG. 6, fluid portion PRa should only be injected to completely bury gap VD as shown in FIG. 8.

### Second Embodiment

Referring to FIG. 9, a silicon carbide substrate 80b in the present embodiment has a bonding portion BDb instead of bonding portion BDa (FIG. 3). Bonding portion BDb has fine particle portion FG and a coarse particle portion GR. Coarse particle portion GR has a particle size exceeding 1 μm. More specifically, coarse particle portion GR is made of particles having a maximum length exceeding 1 μm. The particle size above is, for example, approximately several μm.

Coarse particle portion GR is preferably composed of silicon carbide. It is noted that a material for coarse particle portion GR is not limited to silicon carbide, and any material in a solid state in a stable manner at a maximum temperature at which a silicon carbide substrate is placed during manufacturing of a semiconductor manufacturing apparatus, that is, normally around 1600° C., can be employed. In other words, coarse particle portion GR should only be made of a material having a melting point not lower than 1600° C. For example, boron nitride (BN), silicon nitride (SiN), tungsten carbide (WC), tantalum carbide (TaC), or a refractory metal can be employed.

Fine particle portion FG occupies 2 volume % or more and preferably 30 volume % or more of bonding portion BDb. For example, bonding portion BDb is constituted of 50 volume % of fine particle portion FG and 50 volume % of coarse particle portion GR.

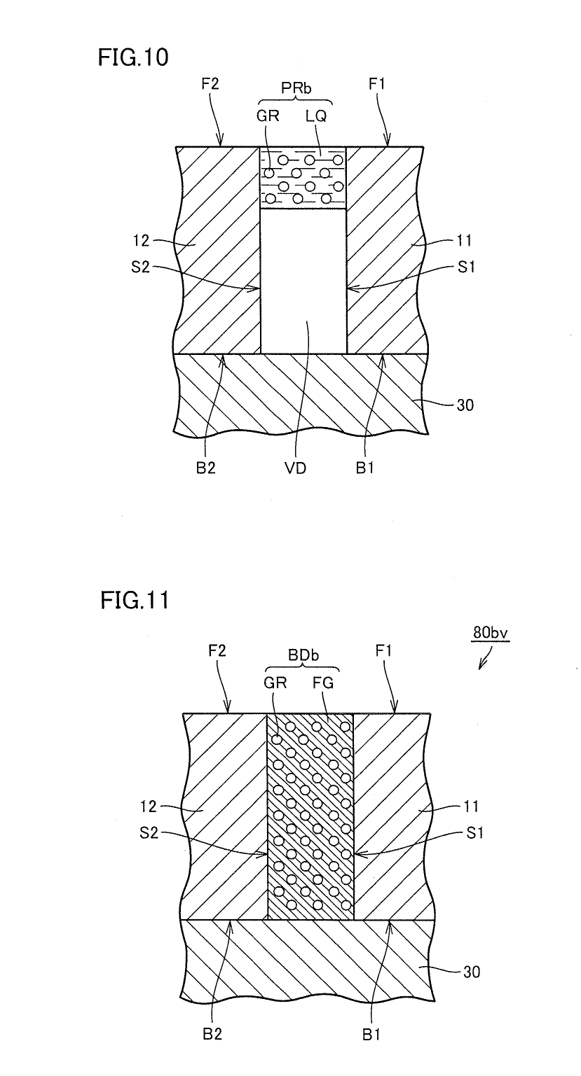

Referring to FIG. 10, in manufacturing of silicon carbide substrate 80b, a fluid portion PRb is formed instead of fluid portion PRa (FIG. 6) in the first embodiment. Fluid portion PRb has a liquid portion LQ and coarse particle portion GR. Fluid portion PRb can be formed by using a fluid in which coarse particles corresponding to coarse particle portion GR have been dispersed (mixed) in a liquid corresponding to liquid portion LQ. By subjecting this fluid portion PRb to heat treatment as in the first embodiment, silicon carbide substrate 80b is obtained.

Since the features other than the above are substantially the same as those in the first embodiment described above, the same or corresponding elements have the same reference characters allotted and description thereof will not be repeated.

According to the present embodiment, fluid portion PRb (FIG. 10) includes coarse particle portion GR of which volume is hardly changed during heat treatment. Thus, decrease in volume due to change from fluid portion PRb to bonding portion BDb during heat treatment can be suppressed. Thus, bonding portion BDb sufficient for closing gap VD can more reliably be formed.

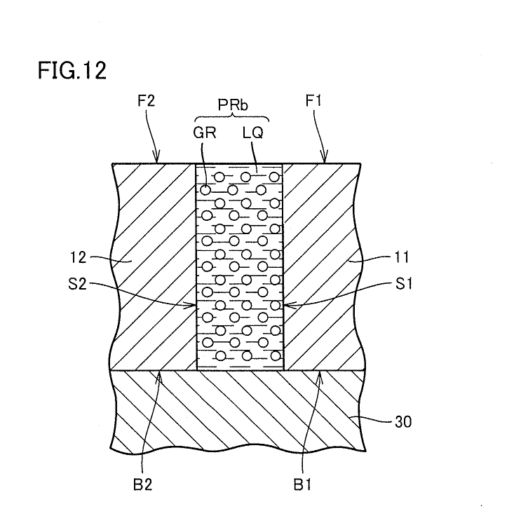

Though a case where gap VD (FIG. 9) remains has been described above, gap VD may be buried completely by bonding portion BDb as shown in FIG. 11. To that end, instead of the step shown in FIG. 10, fluid portion PRb should only be injected to completely bury gap VD as shown in FIG. 12.

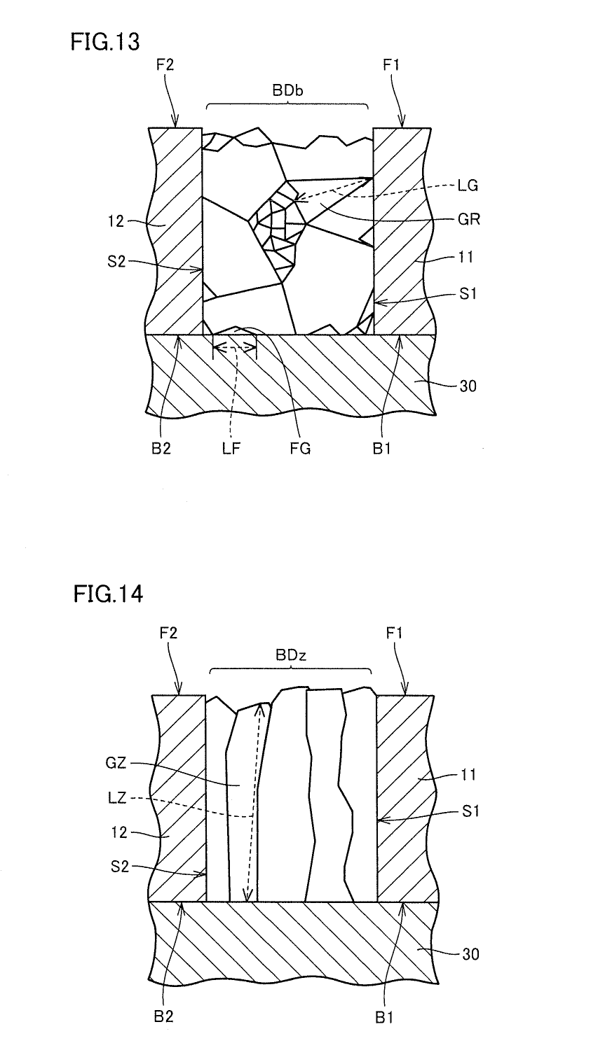

A microstructure of bonding portion BDb (FIG. 11) will now be described in further detail. As shown in FIG. 13, in a cross-sectional view of bonding portion BDb in parallel to a direction of thickness, a ratio of an area of a region occupied by a portion having a maximum length LF not greater than 1 μm (mainly a portion corresponding to fine particle portion FG) to the total area of the cross-sectional view of bonding portion BDb is not lower than 2%. It is noted that, in FIG. 13, a portion having a maximum length LG exceeding 1 μm in the cross-sectional view is formed from coarse particle portion GR. In a case where coarse particle portion GR is not provided as in the first embodiment, a portion having maximum length LG exceeding 1 μm may not be observed in the cross-sectional view. Preferably, in any cross-sectional view of bonding portion BDb, a ratio of an area of a region occupied by a portion having maximum length LF not greater than 1 μm to the total area of the cross-sectional view of bonding portion BDb is not lower than 2%.

In contrast, a bonding portion BDz (FIG. 14) in a comparative example is formed between single crystal substrates 11 and 12 with a sublimation recrystallization method, and in a cross-sectional view, it is substantially occupied by a huge particle portion GZ having a maximum length LZ exceeding 1 μm (typically exceeding 10 μm). Maximum length LZ extends substantially along a direction of thickness (in the drawing, a vertical direction). Huge particle portion GZ typically also has a minimum length exceeding 10 μm. As bonding portion BDz thus has a large particle size, there are few grain boundaries in bonding portion BDz and hence a function to mitigate stress by a grain boundary cannot sufficiently be obtained.

### Third Embodiment

In the present embodiment, a particular case where supporting portion 30 is made of silicon carbide in the method for manufacturing combined substrate 80P (FIGS. 4, 5) used in the first embodiment will be described in detail. For simplification of description below, only single crystal substrates 11 and 12 among single crystal substrates 11 to 19 (FIGS. 4, 5) may be mentioned, however, single crystal substrates 13 to 19 are also handled similarly to single crystal substrates 11 and 12.

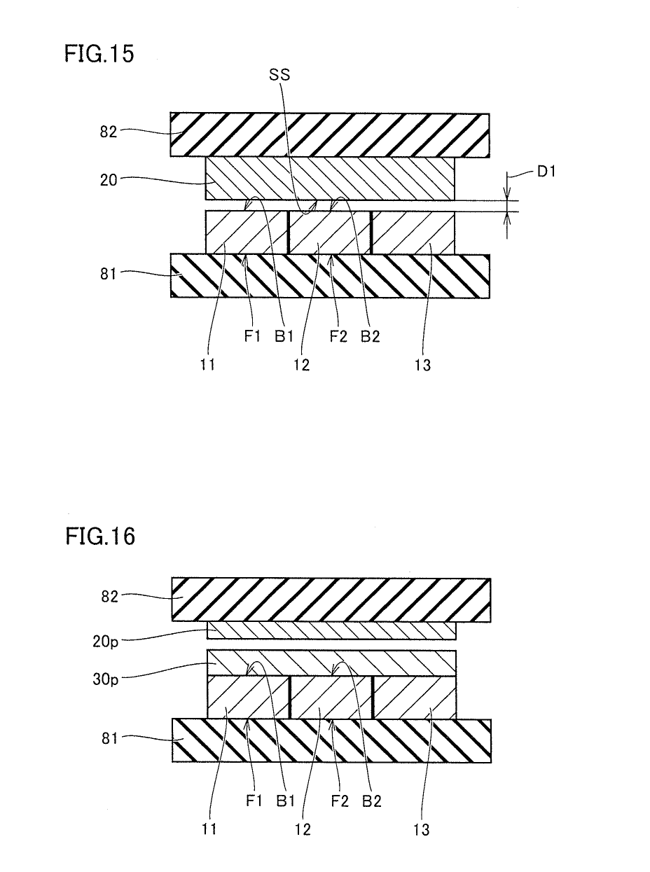

Referring to FIG. 15, single crystal substrates 11 and 12 having single crystal structure are prepared. For example, this step is performed by slicing a silicon carbide ingot grown on the (0001) plane in the hexagonal system. Preferably, back surfaces B1 and B2 have roughness Ra not greater than 100 μm. In addition, preferably a {0001} plane or a {03-38} plane, more preferably a (000-1) plane or a (03-3-8) plane, is adopted as a crystal plane of the surface of each of single crystal substrates 11 and 12.

Then, single crystal substrates 11 and 12 are arranged on a heating member 81 in a processing chamber with each of back surfaces B1 and B2 being exposed in one direction (upward in FIG. 15). Namely, in a plan view, single crystal substrates 11 and 12 are arranged side by side.

Preferably, the arrangement above is such that back surfaces B1 and B2 are flush with each other or front surfaces F1 and F2 are flush with each other.

Then, supporting portion 30 (FIG. 5) connecting back surfaces B1 and B2 to each other is formed in the following manner.

Initially, each of back surfaces B1 and B2 exposed in one direction (upward in FIG. 15) and a surface SS of a solid source material 20 arranged in one direction (upward in FIG. 15) relative to back surfaces B1 and B2 are opposed to each other at a distance D1 from each other. Preferably, an average value of distance D1 is not smaller than 1 μm and not greater than 1 cm.

Solid source material 20 is composed of silicon carbide and is preferably a piece of solid matter of silicon carbide, specifically, an SiC wafer, for example. Solid source material 20 is not particularly limited in terms of crystal structure of SiC. Further preferably, surface SS of solid source material 20 has roughness Ra not greater than 1 mm.

In order to more reliably provide distance D1 (FIG. 15), a spacer 83 (FIG. 18) having a height corresponding to distance D1 may be employed. This method is particularly effective when the average value of distance D1 is approximately 100 μm or greater.

Then, single crystal substrates 11 and 12 are heated by heating member 81 to a prescribed substrate temperature. In addition, solid source material 20 is heated by a heating member 82 to a prescribed source material temperature. When solid source material 20 is thus heated to the source material temperature, SiC is sublimated at surface SS of the solid source material to generate a sublimate, i.e., a gas. This gas is supplied onto back surfaces B1 and B2 from one direction (upward in FIG. 15).

Preferably, the substrate temperature is set lower than the source material temperature, and more preferably set such that a difference between the temperatures is not smaller than 1° C. and not greater than 100° C. Further preferably, the substrate temperature is not lower than 1800° and not higher than 2500° C.

Referring to FIG. 16, the gas supplied as above is solidified and accordingly recrystallized on each of back surfaces B1 and B2. In this way, a supporting portion 30p connecting back surfaces B1 and B2 to each other is formed. Further, solid source material 20 (FIG. 15) is consumed and is reduced in size to be a solid source material 20p.

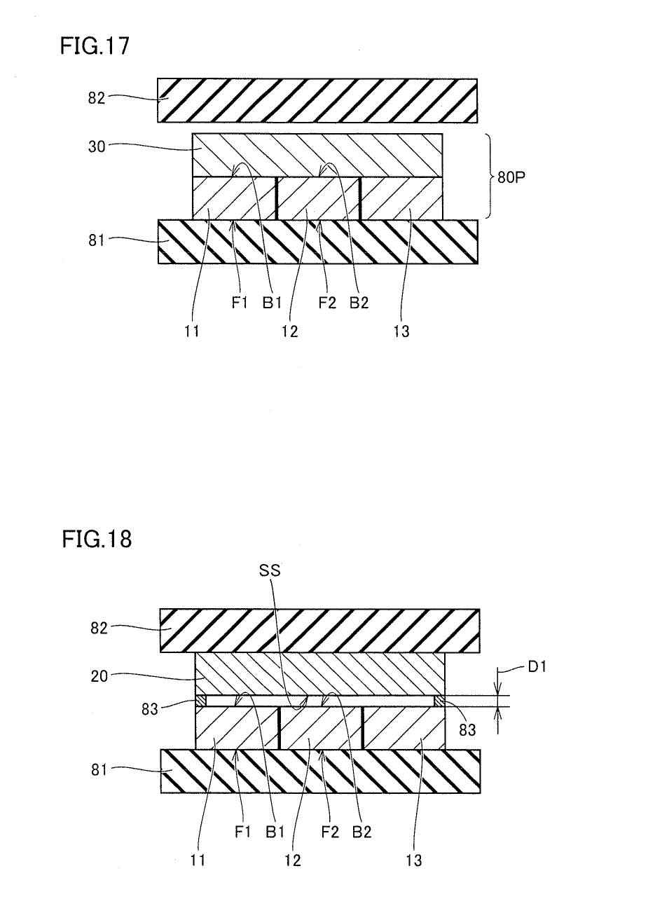

Referring mainly to FIG. 17, as sublimation further develops, solid source material 20p (FIG. 16) is run out. In this way, supporting portion 30 connecting back surfaces B1 and B2 to each other is formed.

Preferably, when supporting portion 30 is formed, an inert gas is employed as an atmosphere in the processing chamber. An exemplary inert gas that can be employed includes a noble gas such as He or Ar, a nitrogen gas, or a mixed gas of a noble gas and a nitrogen gas. When this mixed gas is used, a ratio of the nitrogen gas is set, for example, to 60%. Further, a pressure in the processing chamber is set preferably to 50 kPa or lower and more preferably to 10 kPa or lower.

Further preferably, supporting portion 30 has single crystal structure. More preferably, supporting portion 30 on back surface B1 has a crystal plane inclined by 10° or smaller relative to the crystal plane of back surface B1, or supporting portion 30 on back surface B2 has a crystal plane inclined by 10° or smaller relative to the crystal plane of back surface B2. These angular relations can readily be realized by epitaxially growing supporting portion 30 on each of back surfaces B1 and B2.

Crystal structure of single crystal substrate 11, 12 is preferably of hexagonal system, and more preferably 4H—SiC or 6H—SiC. Moreover, it is preferable that single crystal substrates 11, 12 and supporting portion 30 are made of SiC single crystal having the same crystal structure.

Further preferably, concentration in each of single crystal substrates 11 and 12 is different from impurity concentration in supporting portion 30. More preferably, supporting portion 30 is higher in impurity concentration than each of single crystal substrates 11 and 12. It should be noted that impurity concentration in single crystal substrate 11, 12 is, for example, not lower than 5×10¹⁶ cm⁻³ and not higher than 5×10¹⁹ cm⁻³. Further, impurity concentration in supporting portion 30 is, for example, not lower than 5×10¹⁶ cm⁻³ and not higher than 5×10²¹ cm⁻³. For example, nitrogen or phosphorus can be used as the impurity above.

Further preferably, front surface F1 has an off angle not smaller than 50° and not greater than 65° relative to the {0001} plane of single crystal substrate 11 and front surface F2 has an off angle not smaller than 50° and not greater than 65° relative to the {0001} plane of the single crystal substrate.

More preferably, an off orientation of front surface F1 forms an angle not greater than 5° relative to the <1-100> direction of single crystal substrate 11, and an off orientation of front surface F2 forms an angle not greater than 5° relative to the <1-100> direction of single crystal substrate 12.

Further preferably, front surface F1 has an off angle not smaller than −3° and not greater than 5° relative to the {03-38} plane in the <1-100> direction of single crystal substrate 11, and front surface F2 has an off angle not smaller than −3° and not greater than 5° relative to the {03-38} plane in the <1-100> direction of single crystal substrate 12.

It should be noted that the “off angle of front surface F1 relative to the {03-38} plane in the <1-100> direction” refers to an angle formed by an orthogonal projection of a normal line of front surface F1 to a projection plane defined by the <1-100> direction and the <0001> direction, and a normal line of the {03-38} plane. The sign of positive value corresponds to a case where the orthogonal projection approaches in parallel to the <1-100> direction whereas the sign of negative value corresponds to a case where the orthogonal projection approaches in parallel to the <0001> direction. This is also the case with the “off angle of front surface F2 relative to the {03-38} plane in the <1-100> direction.”

More preferably, an index m in a plane orientation (hklm) of front surface F1 is negative, which is also the case with front surface F2. Namely, each of front surfaces F1 and F2 is a plane close to a (000-1) plane rather than the (0001) plane.

Preferably, the off orientation of front surface F1 forms an angle not greater than 5° relative to the <11-20> direction of single crystal substrate 11, and the off orientation of front surface F2 forms an angle not greater than 5° relative to the <11-20> direction of single crystal substrate 12.

According to the present embodiment, since supporting portion 30 formed on each of back surfaces B1 and B2 is also composed of silicon carbide similarly to single crystal substrates 11 and 12, various physical properties of single crystal substrates 11 and 12 and supporting portion 30 are close to one another. Accordingly, warpage or cracks of combined substrate 80P (FIGS. 4, 5) or silicon carbide substrate 80a (FIGS. 1, 2) resulting from difference in these various physical properties can be suppressed.

Further, by using the sublimation method, supporting portion 30 can be formed fast with high quality. Furthermore, if the sublimation method is a close-spaced sublimation method in particular, supporting portion 30 can more uniformly be formed.

When the average value of distance D1 (FIG. 15) between each of back surfaces B1 and B2 and the surface of solid source material 20 is 1 cm or smaller, distribution in film thickness of supporting portion 30 can be reduced. When the average value of this distance D1 is 1 μm or greater, a space for sublimation of silicon carbide can sufficiently be secured.

In the step of forming supporting portion 30, the temperatures of single crystal substrates 11 and 12 are set lower than that of solid source material 20 (FIG. 15). Thus, sublimated SiC can efficiently be solidified on single crystal substrates 11 and 12.

Further preferably, the step of arranging single crystal substrates 11 and 12 is performed such that a shortest distance between single crystal substrates 11 and 12 is set to 1 mm or smaller. Accordingly, supporting portion 30 can be formed to more reliably connect back surface B1 of single crystal substrate 11 and back surface B2 of single crystal substrate 12 to each other.

Further preferably, supporting portion 30 has single crystal structure. Accordingly, supporting portion 30 can have various physical properties close to various physical properties of each of single crystal substrates 11 and 12 similarly having single crystal structure.

More preferably, supporting portion 30 on back surface B1 has a crystal plane inclined by 10° or smaller relative to that of back surface B1. Further, supporting portion 30 on back surface B2 has a crystal plane inclined by 10° or smaller relative to that of back surface B2. Accordingly, supporting portion 30 can have anisotropy close to that of each of single crystal substrates 11 and 12.

Further preferably, each of single crystal substrates 11 and 12 is different in impurity concentration from supporting portion 30. Accordingly, silicon carbide substrate 80a (FIG. 2) having a structure of two layers different in impurity concentration can be obtained.

Further preferably, supporting portion 30 is higher in impurity concentration than each of single crystal substrates 11 and 12. Thus, supporting portion 30 can be lower in resistivity than each of single crystal substrates 11 and 12. Accordingly, silicon carbide substrate 80a suitable for manufacturing a semiconductor device in which a current flows in a thickness direction of supporting portion 30, that is, a semiconductor device of vertical type, can be obtained.

Further preferably, front surface F1 has an off angle not smaller than 50° and not greater than 65° relative to the {0001} plane of single crystal substrate 11 and front surface F2 has an off angle not smaller than 50° and not greater than 65° relative to the {0001} plane of single crystal substrate 12. Thus, channel mobility in front surfaces F1 and F2 can be enhanced as compared with a case where front surfaces F1 and F2 are the {0001} plane.

More preferably, the off orientation of front surface F1 forms an angle not greater than 5° relative to the <1-100> direction of single crystal substrate 11, and the off orientation of front surface F2 forms an angle not greater than 5° relative to the <1-100> direction of single crystal substrate 12. Thus, channel mobility in front surfaces F1 and F2 can further be enhanced.

Further preferably, front surface F1 has an off angle not smaller than −3° and not greater than 5° relative to the {03-38} plane in the <1-100> direction of single crystal substrate 11, and front surface F2 has an off angle not smaller than −3° and not greater than 5° relative to the {03-38} plane in the <1-100> direction of single crystal substrate 12. Thus, channel mobility in front surfaces F1 and F2 can further be enhanced.

Further preferably, the off orientation of front surface F1 forms an angle not greater than 5° relative to the <11-20> direction of single crystal substrate 11, and the off orientation of front surface F2 forms an angle not greater than 5° relative to the <11-20> direction of single crystal substrate 12. Thus, channel mobility in front surfaces F1 and F2 can be enhanced as compared with a case where front surfaces F1 and F2 are the {0001} plane.

In the description above, an SiC wafer is exemplified as solid source material 20, however, solid source material 20 is not limited thereto and may be, for example, SiC powders or an SiC sintered compact.

In FIG. 15, each of back surfaces B1 and B2 and surface SS of solid source material 20 are spaced apart from each other across them, however, each of back surfaces B1 and B2 and surface SS of solid source material 20 may be spaced apart from each other while back surfaces B1 and B2 and surface SS of solid source material 20 are partially in contact with each other. Two variations corresponding to this case will be described below.

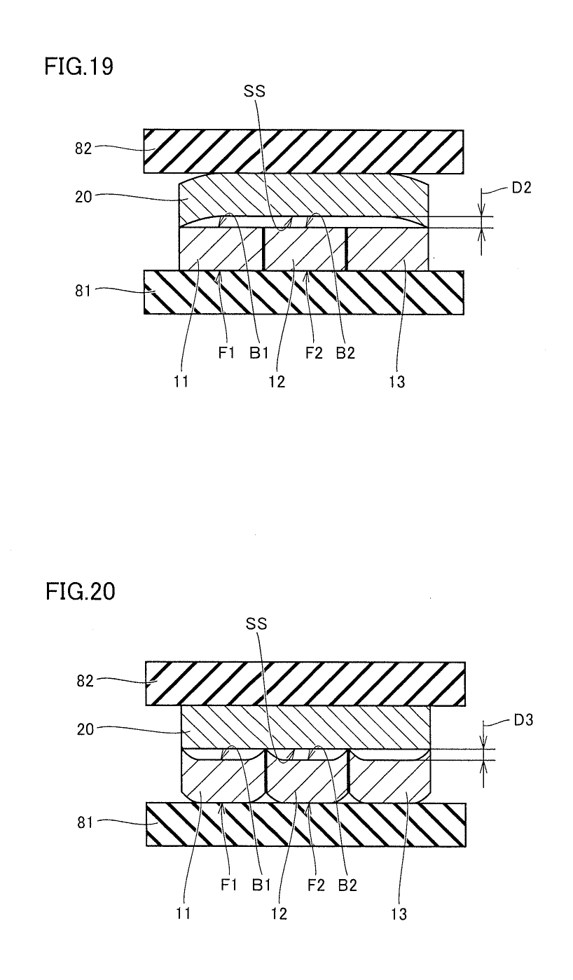

Referring to FIG. 19, in this example, the space above is secured by warpage of the SiC wafer serving as solid source material 20. More specifically, in the present example, a distance D2 is locally zero, however, an average value thereof never fails to exceed zero. Further preferably, similarly to the average value of distance D1, an average value of distance D2 is not smaller than 1 μm and not greater than 1 cm.

Referring to FIG. 20, in this example, the space above is secured by warpage of single crystal substrates 11 to 13. More specifically, in the present example, a distance D3 is locally zero, however, an average value thereof never fails to exceed zero. Further preferably, similarly to the average value of distance D1, an average value of distance D3 is not smaller than 1 μm and not greater than 1 cm.

It is noted that the space above may be secured by combination of the methods in FIG. 19 and FIG. 20, that is, by both of warpage of the SiC wafer serving as solid source material 20 and warpage of single crystal substrates 11 to 13.

The method in each of FIG. 19 and FIG. 20 or the method based on combination of these methods is particularly effective when the average value of the distance above is not greater than 100 μm.

### Fourth Embodiment

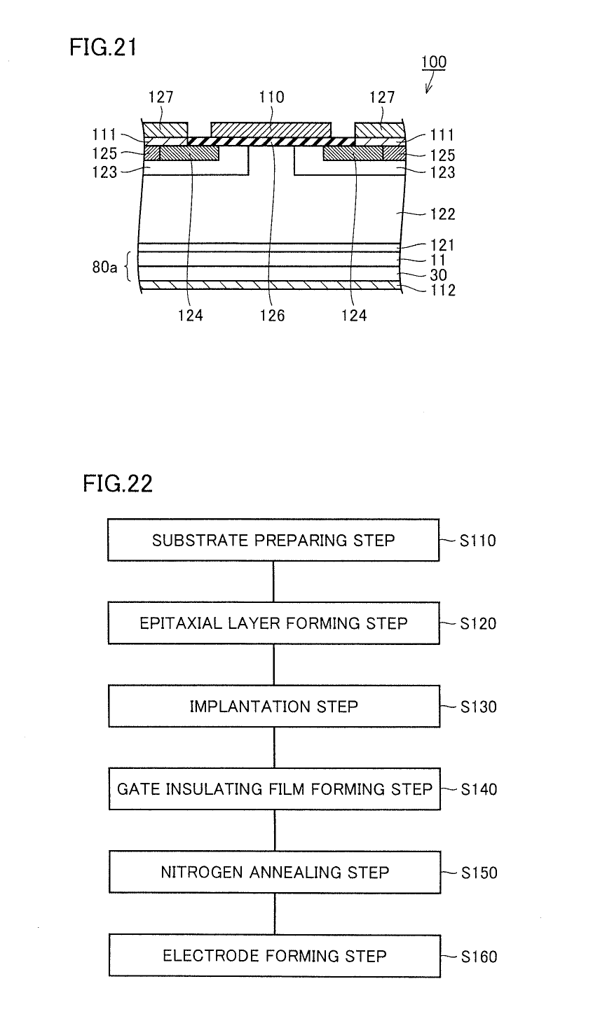

Referring to FIG. 21, a semiconductor device 100 in the present embodiment is a vertical DiMOSFET (Double Implanted Metal Oxide Semiconductor Field Effect Transistor), and it has silicon carbide substrate 80a, a buffer layer 121, a reverse breakdown voltage holding layer 122, a p region 123, an n⁺ region 124, a p⁺ region 125, an oxide film 126, a source electrode 111, an upper source electrode 127, a gate electrode 110, and a drain electrode 112.

In the present embodiment, silicon carbide substrate 80a has an n conductivity type, and has supporting portion 30 and single crystal substrate 11 as described in the first embodiment. Drain electrode 112 is provided on supporting portion 30 such that supporting portion 30 lies between drain electrode 112 and single crystal substrate 11. Buffer layer 121 is provided on single crystal substrate 11 such that single crystal substrate 11 lies between buffer layer 121 and supporting portion 30.

Buffer layer 121 has an n conductivity type, and has a thickness, for example, of 0.5 μm. Further, concentration of an n-type conductive impurity in buffer layer 121 is, for example, 5×10¹⁷ cm⁻³.

Reverse breakdown voltage holding layer 122 is formed on buffer layer 121, and made of silicon carbide having an n conductivity type. For example, reverse breakdown voltage holding layer 122 has a thickness of 10 μm, and concentration of an n-type conductive impurity therein is 5×10¹⁵ cm⁻³.

In the surface of this reverse breakdown voltage holding layer 122, a plurality of p regions 123 having a p conductivity type are formed at a distance from each other. In p region 123, n⁺ region 124 is formed in a surface layer of p region 123. Further, at a position adjacent to this n⁺ region 124, p⁺ region 125 is formed. Oxide film 126 is formed to extend from n⁺ region 124 in one p region 123 over p region 123, reverse breakdown voltage holding layer 122 exposed between two p regions 123, and the other p region 123 to n⁺ region 124 in the other p region 123. On oxide film 126, gate electrode 110 is formed. Further, source electrode 111 is formed on n⁺ region 124 and p⁺ region 125. On source electrode 111, upper source electrode 127 is formed.

A maximum value of concentration of nitrogen atoms is not lower than 1×10²¹ cm⁻³ in a region within 10 nm from an interface between oxide film 126 and each of n⁺ region 124, p⁺ region 125, p region 123, and reverse breakdown voltage holding layer 122 serving as semiconductor layers. Thus, mobility particularly in a channel region below oxide film 126 (a portion of p region 123 between n⁺ region 124 and reverse breakdown voltage holding layer 122, in contact with oxide film 126) can be improved.

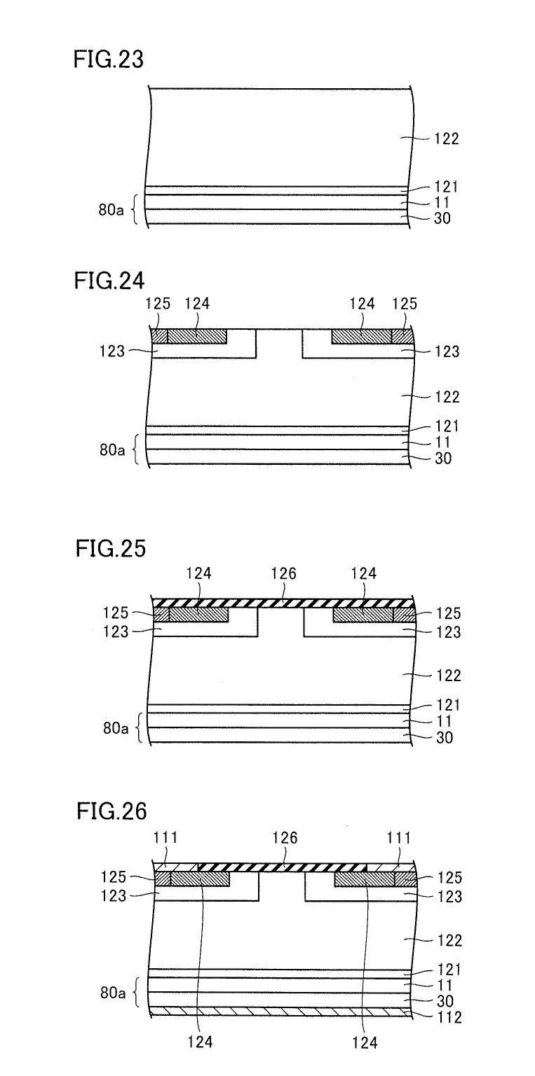

A method for manufacturing semiconductor device 100 will now be described. It should be noted that FIGS. 23 to 26 show only steps in the vicinity of single crystal substrate 11 among single crystal substrates 11 to 19 (FIG. 1), however, similar steps are performed also in the vicinity of each of single crystal substrate 12 to single crystal substrate 19.

Initially, in a substrate preparing step (step S110: FIG. 22), silicon carbide substrate 80a (FIGS. 1 and 2) is prepared. Silicon carbide substrate 80a has an n conductivity type.

Referring to FIG. 23, in an epitaxial layer forming step (step S120: FIG. 22), buffer layer 121 and reverse breakdown voltage holding layer 122 are formed as follows.

Initially, buffer layer 121 is formed on the surface of silicon carbide substrate 80a. Buffer layer 121 is composed of silicon carbide having an n conductivity type, and it is an epitaxial layer having a thickness, for example, of 0.5 μm. Concentration of a conductive impurity in buffer layer 121 is, for example, 5×10¹⁷ cm⁻³.

Then, reverse breakdown voltage holding layer 122 is formed on buffer layer 121. Specifically, a layer composed of silicon carbide having an n conductivity type is formed with an epitaxial growth method. Reverse breakdown voltage holding layer 122 has a thickness, for example, of 10 μm. Concentration of an n-type conductive impurity in reverse breakdown voltage holding layer 122 is, for example, 5×10¹⁵ cm⁻³.

Referring to FIG. 24, in an implantation step (step S130: FIG. 22), p region 123, n⁺ region 124, and p⁺ region 125 are formed as follows.

Initially, an impurity having a p conductivity type is selectively implanted into a part of reverse breakdown voltage holding layer 122, to thereby form p region 123. Then, an n-type conductive impurity is selectively implanted into a prescribed region to thereby form n⁺ region 124, and a conductive impurity having a p conductivity type is selectively implanted into a prescribed region to thereby form p⁺ region 125. It should be noted that such selective implantation of impurities is performed using a mask formed, for example, from an oxide film.

After such an implantation step, activation annealing treatment is performed. For example, annealing is performed in an argon atmosphere at a heating temperature of 1700° C. for 30 minutes.

Referring to FIG. 25, a gate insulating film forming step (step S140: FIG. 22) is performed. Specifically, oxide film 126 is formed to cover reverse breakdown voltage holding layer 122, p region 123, n⁺ region 124, and p⁺ region 125. Formation may be achieved through dry oxidation (thermal oxidation). Conditions for dry oxidation are, for example, such that a heating temperature is set to 1200° C. and a heating time period is set to 30 minutes.

Thereafter, a nitrogen annealing step (step S150) is performed. Specifically, annealing treatment is performed in a nitrogen monoxide (NO) atmosphere. Conditions for this treatment are, for example, such that a heating temperature is set to 1100° C. and a heating time period is set to 120 minutes. As a result, nitrogen atoms are introduced in the vicinity of the interface between oxide film 126 and each of reverse breakdown voltage holding layer 122, p region 123, n⁺ region 124, and p⁺ region 125.

It should be noted that, after this annealing step using nitrogen monoxide, annealing treatment using an argon (Ar) gas representing an inert gas may further be performed. Conditions for this treatment are, for example, such that a heating temperature is set to 1100° C. and a heating time period is set to 60 minutes.

Referring to FIG. 26, in an electrode forming step (step S160: FIG. 22), source electrode 111 and drain electrode 112 are formed in the following manner.

Initially, a resist film having a pattern is formed on oxide film 126 with a photolithography method. Using this resist film as a mask, a portion of oxide film 126 located on n⁺ region 124 and p⁺ region 125 is etched away. In this way, an opening is formed in oxide film 126. Then, in the opening, a conductor film is formed in contact with each of n⁺ region 124 and p⁺ region 125. Then, the resist film is removed, to thereby remove the portion of the conductor film located on the resist film (lift-off). This conductor film may be a metal film, and for example, it may be made of nickel (Ni). As a result of lift-off, source electrode 111 is formed.

It should be noted that heat treatment for alloying is preferably performed here. For example, heat treatment is performed in an atmosphere of an argon (Ar) gas, which is an inert gas, at a heating temperature of 950° C. for two minutes.

Referring again to FIG. 21, upper source electrode 127 is formed on source electrode 111. Further, drain electrode 112 is formed on the back surface of silicon carbide substrate 80a. Semiconductor device 100 is obtained as above.

It is noted that a configuration in which conductivity types are interchanged in the present embodiment, that is, a configuration in which p-type and n-type are interchanged, may also be employed.

Further, a silicon carbide substrate for fabricating semiconductor device 100 is not limited to silicon carbide substrate 80a in the first embodiment, and may be, for example, the silicon carbide substrate in the second or third embodiment or the silicon carbide substrate in the variation of each embodiment.

Further, though the vertical DiMOSFET has been exemplified, another semiconductor device may be manufactured using the silicon carbide substrate according to the present invention. For example, a RESURF-JFET (Reduced Surface Field-Junction Field Effect Transistor) or a Schottky diode may be manufactured.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide substrate, comprising:
a first single crystal substrate having a first side surface and composed of silicon carbide;
a second single crystal substrate having a second side surface opposed to said first side surface and composed of silicon carbide; and
a bonding portion connecting said first and second side surfaces to each other between said first and second side surfaces,
at least a part of said bonding portion being made of particles having a maximum length not greater than 1 μm and composed of silicon carbide.

2. The silicon carbide substrate according to claim 1, wherein
said at least a part of said bonding portion occupies 30 volume % or more of said bonding portion.

3. The silicon carbide substrate according to claim 1, wherein
said bonding portion includes particles having a maximum length exceeding 1 μm and composed of a material having a melting point not lower than 1600° C.

4. The silicon carbide substrate according to claim 1, further comprising a supporting portion supporting each of said first and second single crystal substrates.

5. The silicon carbide substrate according to claim 4, wherein
said supporting portion is composed of silicon carbide.

6. A silicon carbide substrate, comprising:
a first single crystal substrate having a first side surface and composed of silicon carbide;
a second single crystal substrate having a second side surface opposed to said first side surface and composed of silicon carbide; and
a bonding portion connecting said first and second side surfaces to each other between said first and second side surfaces,
in a cross-sectional view of said bonding portion, a ratio of an area of a region occupied by particles composed of silicon carbide and having a maximum length not greater than 1 μm to a total area of the cross-sectional view of said bonding portion being not lower than 2%.

7. The silicon carbide substrate according to claim 6, wherein
said bonding portion includes in the cross-sectional view, particles composed of silicon carbide and having a maximum length exceeding 1 μm.

8. The silicon carbide substrate according to claim 6, further comprising a supporting portion supporting each of said first and second single crystal substrates.

9. The silicon carbide substrate according to claim 8, wherein
said supporting portion is composed of silicon carbide.

10. A method of manufacturing a silicon carbide substrate, comprising the steps of:
preparing a combined substrate including a first single crystal substrate having a first back surface and a first side surface, a second single crystal substrate having a second back surface and a second side surface, and a supporting portion bonded to each of said first and second back surfaces, a gap having an opening being formed between said first and second side surfaces as a result of said first and second side surfaces opposed to each other;
forming a fluid portion connecting said first and second side surfaces to each other by injecting a fluid containing at least any of polycarbosilane and a derivative thereof through said opening of said gap; and
forming a bonding portion burying at least a part of said gap by solidifying said fluid portion through heat treatment.

11. The method of manufacturing a silicon carbide substrate according to claim 10, wherein
in said step of forming a bonding portion, said heat treatment is performed at a temperature not lower than 800° C. and not higher than 2000° C.

12. The method of manufacturing a silicon carbide substrate according to claim 10, wherein
the step of forming a fluid portion includes the step of mixing in said fluid, particles having a maximum length exceeding 1 μm and composed of a material having a melting point not lower than 1600° C.

13. The method of manufacturing a silicon carbide substrate according to claim 10, wherein
said supporting portion is composed of silicon carbide.
